(19) United States
(12) Patent Application Publication
(10) Pub. No.: US 2008/0254377 A1
(43) Pub. Date: Oct. 16, 2008

(54) METAL PHOTOMASK POD AND FILTER DEVICE THEREOF

(76) Inventors: Chien-Ta CHEN, Shulin City (TW); Ming-Chien Chiu, Shulin City (TW)

Correspondence Address: SINORICA, LLC, 528 FALLSGROVE DRIVE, ROCKVILLE, MD, 20850, US

(21) Appl. No.: 12/141,158

(22) Filed: Jun. 18, 2008

Related U.S. Application Data
(63) Continuation-in-part of application No. 11/640,887, filed on Dec. 19, 2006.

(30) Foreign Application Priority Data
Jul. 13, 2007 (TW) 096211416

(51) Int. Cl. G03F 1/00

(52) U.S. Cl. 430/5

(57) ABSTRACT

A metal photomask pod with a filter device and with atmoseal function is provided. The metal photomask pod includes a metal upper cover and a metal lower cover coupled to form an inner space for receiving a photomask. A side portion of the metal upper cover or the metal lower cover of the photomask pod includes at least one through hole for communicating the inner space with an outer space of the photomask pod. A filter device covers the through hole.

### CROSS-REFERENCE TO RELATED APPLICATIONS

This application is a continuation-in-part of U.S. patent application Ser. No. 11/640,887, filed on Dec. 19, 2006 in the U.S. Patent and Trademark Office, the disclosures of which are incorporated herein by reference.

### BACKGROUND OF THE INVENTION

1. Field of the Invention

The present invention relates to photomask pods, and more particularly, to a metal photomask pod and a filter device of the photomask pod.

2. Description of Related Art

With rapid development in semiconductor technology, optical lithography has been playing an important role in defining patterns. The application of optical lithography in semiconductor involves fabricating a light transmissible photomask of a particular shape with a pre-designed circuitry pattern defined therein. As a light source is projected onto a silicon wafer through the photomask, the circuitry pattern of the photomask can be exposed onto the silicon wafer. The photomask used for producing the pattern must be maintained to be very clean because any particles adhered on the photomask (e.g., particulates, dust or organic matters) can deteriorate the imaging quality. Therefore, wafer processing is typically performed in a clean room to prevent contamination by particles in the air. Current clean room, however, cannot obtain an absolutely clean condition.

Therefore, anti-contamination photomask pods are usually used for photomask storage and transportation to keep cleanness of the photomask in modern semiconductor process. The photomask pod is used to store the photomask during the semiconductor process, facilitating transporting the reticle between various equipments and isolating the photomask from the air to avoid photomask contamination. Hence, in advanced semiconductor factories, cleanness of the photomask pod is usually required to be standard mechanical interface (SMIF) compatible, i.e., the photomask pod is maintained at a cleanliness of class 1. One way to achieve such cleanliness is to charge the photomask pod with gas.

However, to further increase the product yield and reduce the manufacturing cost, in addition to meeting the cleanness standard, photomask contamination caused by exotic gases needs to be avoided. The exotic gas has two sources other than the atmosphere. One source is the outgasing of the photomask pod itself that is made of high polymer materials, and the other source is the volatilization gas of residual trace chemical solution on the surface of the photomask pod. Atomization of these undesired gases may occur on the surface of the photomask pod, which causes the reticle pod to become unusable thus increasing the manufacturing cost. Charging the photomask pod with gas is one of the current ways to solve the gas atomization. How to keep the cleanness of the charged gas has become an important subject.

Furthermore, conventional photomask pods are usually made of high polymer materials, because of the advantages of the high polymer materials including, easy molding, low cost, and the capability of forming transparent member. However, the high polymer materials with high conductive resistance can easily generate electrostatic charges from friction or detaching. Especially in a clean room environment where a low humidity needs to be maintained, the photomask pod of high polymer materials can extremely easily generate and accumulate electrostatic charges. The electrostatic charges on the surface of the photomask pod can easily attract the particles in the air, and in an even worse situation, may cause electrostatic discharge (ESD) of the metal wires on the photomask. The transient current generated by the ESD may generate spark or arc. Accompanying with the spark or arc is high current and high temperature, which causes the metal wires to be oxidated and melted, resulting in a change in the pattern of the photomask.

Currently, there are many ways to solve the ESD problem. These ways includes improving the operation environment by maintaining an appropriate humidity in the air, letting the operator wear clothes having grounding function, and eliminating the electrostatic charges with an ion fan. However, there are many unpredictable factors in changing the operation environment, which makes it impossible to completely eliminate the damage to the photomask that may be caused by the electrostatic charges.

Accordingly, the present invention provides an improved photomask pod with a filter device to overcome the above-mentioned problems.

### SUMMARY OF THE INVENTION

To overcome one or more problems in the prior art, the present invention provides a metal photomask pod with a filter device and with atmoseal function. The metal photomask pod includes a metal upper cover and a metal lower cover coupled to form an inner space for receiving a photomask. A side portion of the metal upper cover or the metal lower cover of the photomask pod includes at least one through hole for communicating the inner space with an outer space of the photomask pod. A filter device covers the through hole. The filter device may be integrally formed or formed by multiple pieces. In a preferred embodiment, the filter device may include an elastic sleeve, a clamping member and a filter film. The elastic sleeve is engaged in the through hole. The elastic sleeve has a first opening aligned with the through hole. The clamping member is engaged in the elastic sleeve and has at least one aperture. The aperture is positioned at a location corresponding to the first opening of the elastic sleeve. The filter film is disposed in the clamping device where the aperture is formed.

In another aspect, the metal upper cover of the metal photomask pod includes a side portion defining an opening. The metal lower cover of the metal photomask pod includes a side portion defining an opening corresponding to the opening of the metal upper cover. A seal gasket is disposed on the side portion of the upper cover or the side portion of the lower cover, such that the inner space is sealed. The seal gasket is engaged on the side portion of the upper cover or the lower cover in a clip manner.

Accordingly, in one aspect, the present invention provides a photomask pod that can reduce electrostatic accumulation and prevent the damage to the photomask caused by ESD.

In another aspect, the present invention provides a photomask pod that can position the photomask with a pressing device to prevent the damage to the photomask caused by impact during transportation.

In another aspect, the present invention provides a photomask pod that includes a side portion with a plate, which allows the photomask pod to be vertically placed. A label can also be attached on the plate for identifying the item in the photomask pod.

In another aspect, the present invention provides a photomask pod that includes a side portion with at least one protrusion, which allows the photomask pod to be vertically placed.

In another aspect, the present invention provides a filter device that can filter dusts in the air to prevent photomask contamination.

In another aspect, the present invention provides a filter device that can filter dusts in the air to keep the cleanliness in the photomask pod.

In another aspect, the present invention provides a filter device that engages in the photomask pod in a latch manner to prevent generation of the particles thus reducing the contamination source.

In another aspect, the present invention provides a sealing device that provides a good sealing result when the upper and lower covers of the metal photomask pod are coupled.

In still another aspect, the present invention provides a sealing device that can keep the cleanliness of the gas in the photomask pod to avoid the photomask contamination.

### BRIEF DESCRIPTION OF THE DRAWINGS

FIGS. 1A and 1B illustrate a preferred embodiment of the metal photomask pod.

FIG. 1C illustrates an embodiment of the protrusion of the metal photomask pod.

FIG. 2A illustrates an embodiment of the filter device.

FIG. 2B illustrates an embodiment of the elastic sleeve.

FIG. 2C illustrates an embodiment of the clamping member.

FIGS. 3A to 3C illustrate an embodiment of the engagement of the photomask pod with the filter device.

FIG. 4A illustrates an embodiment of the photomask pod and the sealing gasket.

FIG. 4B illustrates an embodiment of the sealing gasket.

FIG. 4C illustrates an embodiment of the photomask pod and the sealing gasket.

FIGS. 5A to 5C illustrate an embodiment of the pressing member.

### DETAILED DESCRIPTION OF THE PREFERRED EMBODIMENTS

The present invention discloses a photomask pod with a filter device. Manufacturing or processing of the photomask or photomask pod are conducted using existing technology and are therefore not described in detail in the following description. Also, before at least one embodiment of the invention is explained in detail, it is to be understood that the drawings referred to in the following description are merely schematic views showing features of the present invention and are not made according to actual dimensions.

A metal photomask pod is provided to solve the electrostatic discharge (ESD) problem. However, because the photomask pod is made of high polymer materials, when upper and lower covers are assembled, the photomask pod is made to have elasticity, facilitating airtight combination between the upper and lower covers. When the photomask pod is made of a metal material, airtight combination between the upper and lower covers may not be easy to achieve. Therefore, an edge of the cover needs to be specially processed to form a latch portion to achieve the airtight combination between the upper and lower covers. However, the special processing on the covers of the metal photomask pod involves complex design and also incurs a cost increase of the photomask pod.

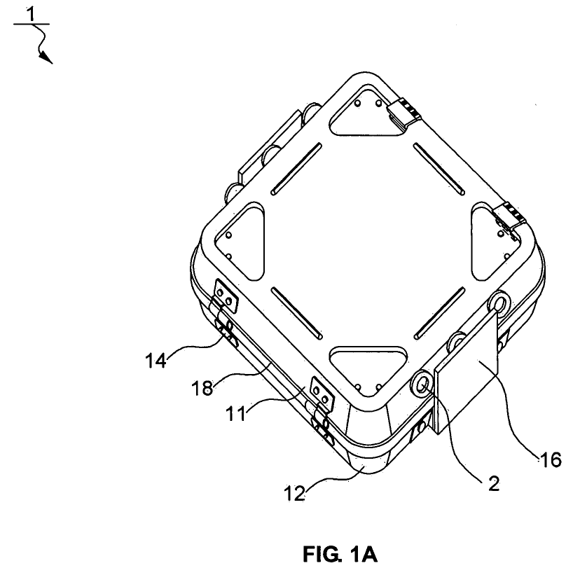

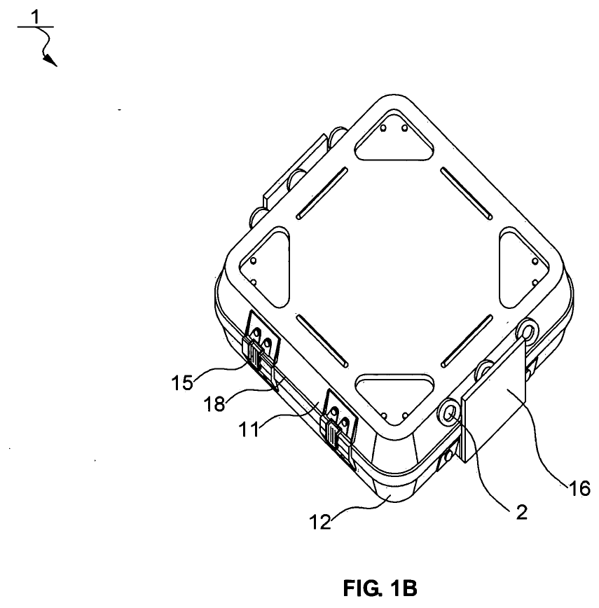

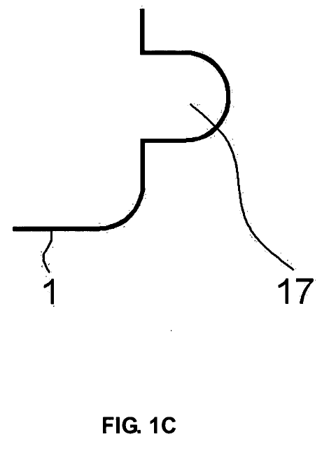

FIGS. 1A and 1B illustrate a preferred embodiment of the metal photomask pod. The metal photomask pod 1 includes a metal upper cover 11 and a metal lower cover 12. The metal upper cover 11 and the metal lower cover 12 are coupled together to cooperatively form an inner space for receiving a photomask. The metal photomask pod 1 may be made of stainless steel, aluminum alloy or magnesium alloy, for example. A side portion of the metal upper cover 11 or the metal lower cover 12 defines a through hole 13 for communicating the inner space with an outer space. A filter device 2 is disposed to cover the through hole 13. In addition, the side portion of the metal photomask pod 1 includes at least one coupling mechanism 14, at least one locking member 15, at least one plate 16 or at least one protrusion 17 (seeing FIG. 1C). A pressing member 3 is disposed in the upper cover 11 or the lower cover 12 of the metal photomask pod 1. The coupling mechanism 14 is configured to couple the metal upper cover 11 to the metal lower cover 12. The locking member 15 made of a high polymer material is configured to lock the metal upper cover 11 and the metal lower cover 12. The plate 16 and the protrusion 17 are configured to allow the photomask pod 1 to be vertically placed. Besides, a label can be attached to the plate 16 for identifying the item contained in the photomask pod 1.

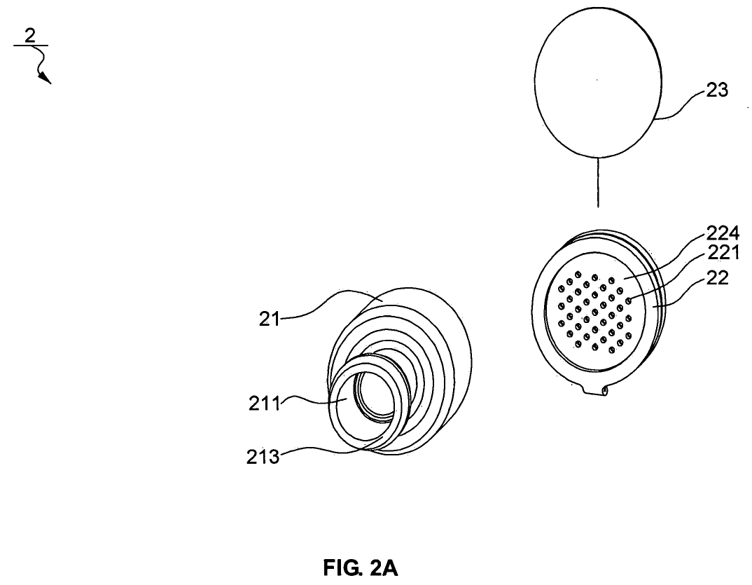

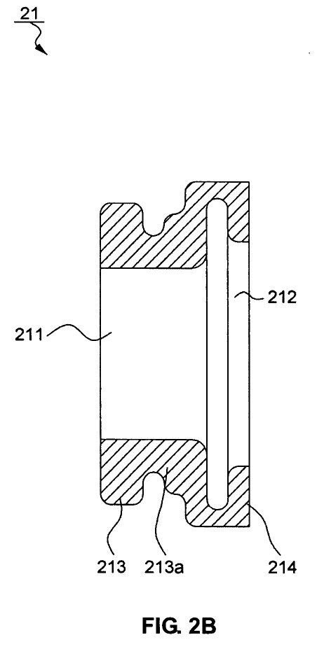

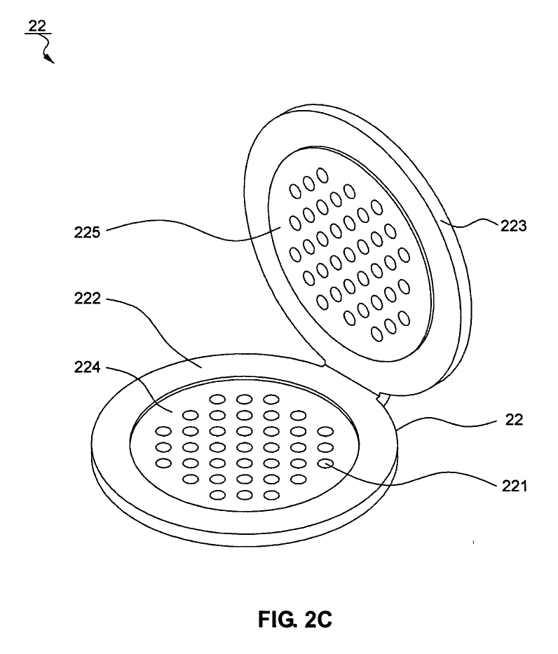

FIG. 2A illustrates a preferred embodiment of the filter device. The filter device 2 includes an elastic sleeve 21, a clamping member 22 and a filter film 23. The elastic sleeve 21 (seeing FIG. 2B) is configured to be engaged in the through hole 13 of the metal photomask pod 1. The elastic sleeve 21 has a first opening 211 and a second opening 212, with the first opening 211 being smaller than the second opening 212. A protruding portion 213 is formed around the first opening 211 and is engaged in the through hole 13. A latch portion 214 is formed around the second opening 212 and latches the clamping member 22. The elastic sleeve 21 is made of a high polymer material, for example. The clamping member 22 (seeing FIG. 2C) is latched in the elastic sleeve 21 and has at least one aperture 221. The aperture 221 is disposed corresponding to the first opening 211 of the elastic sleeve 21. The clamping member 22 includes a first part 222 and a second part 223 each with the aperture 221. The first part 222 and the second part 223 may be symmetrically positioned and integrally formed elements, or separately formed elements. The first part 222 and the second part 223 may have identical configuration. At least one of the first part 222 and the second part 223 of the clamping member 22 includes a concave portion 224, while the other of the first part 222 and the second part 223 includes a convex portion 225. The clamping member 22 is made of a metal material, for example. The filter film 23 is sandwiched between the first part 222 and the second part 223 of the clamping member 22. The filter film 23 is clamped in the clamping member 22 where at least one aperture 221 is formed. The filter film 23 is made of a synthesize fiber, for example.

A preferred embodiment of the clamping member for sandwiching the filter film is provided. Either or both of the first and second parts 222, 223 of the clamping member 22 define a concave portion 224 oriented toward an interior between the first and second parts 222, 223, to define the space for receiving the filter film 23. In another preferred embodiment, the present invention provides another clamping member for sandwiching the filter film. At least one of the first and second parts 222 and 223 of the clamping member 22 includes a concave portion 224, while the other of the first and second parts 222 and 223 includes a convex portion 225. Both the concave portion 224 and the convex portion 225 are oriented toward an interior between the first and second parts 222 and 223. The concave portion 224 is larger than the convex portion 225, allowing the filter film 23 to be sandwiched and positioned therebetween.

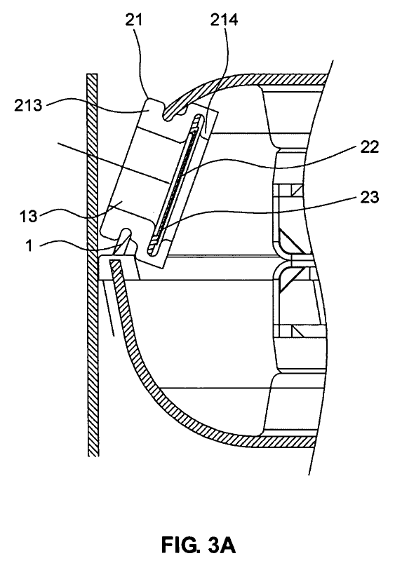

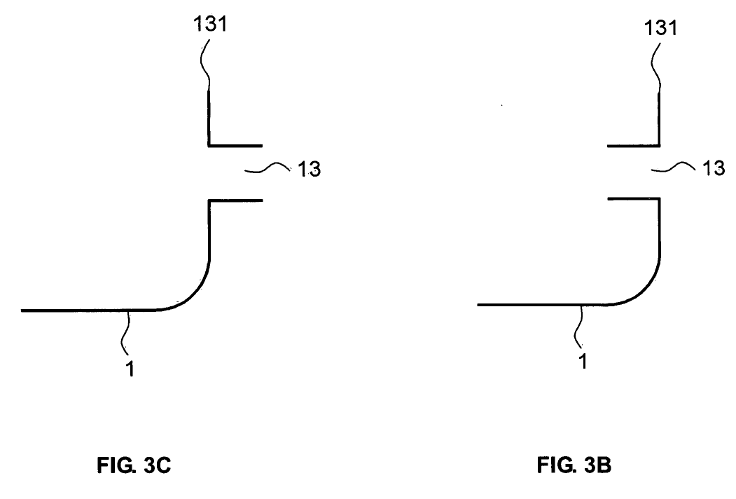

FIG. 3A illustrates a preferred embodiment of the engagement of the photomask pod with the filter device. The elastic sleeve 21 of the filter device 2 engages in the through hole 13 of the photomask pod 1 with its protruding portion 213. The protruding portion 213 includes a groove portion 213a. The groove portion 213a engages the photomask pod 1 at the through hole 13, thereby mounting the filter device 2 on the photomask pod 1. FIG. 3B illustrates another preferred embodiment of the engagement of the photomask pod with the filter device. The photomask pod 1 includes at least one sidewall 131 around the through hole 13, and the protruding portion 213 of the elastic sleeve 21 is engaged with the sidewall 131 of the photomask pod 1. The sidewall 131 is integrally formed with the upper cover 21 or the lower cover 22, or otherwise attached on the photomask pod 1 by welding. The sidewall 131 extends toward the inner space of the photomask pod 1. FIG. 3C illustrates still another preferred embodiment of the engagement of the photomask pod with the filter device. The sidewall 131 extends toward the outer space of the photomask pod 1.

In another embodiment (not shown), the filtering portion of the filter device and the engaging portion within the photomask pod may also be integrally formed. In still another embodiment (not shown), the filter device may include a filter sheet and a hollow frame. The filter sheet and the hollow frame may engage within the sidewall 131 around the through hole 13, thus allowing the filter sheet to be sandwiched between the hollow frame and the photomask pod. In this way, the filter sheet covers the through hole 13 for filtering.

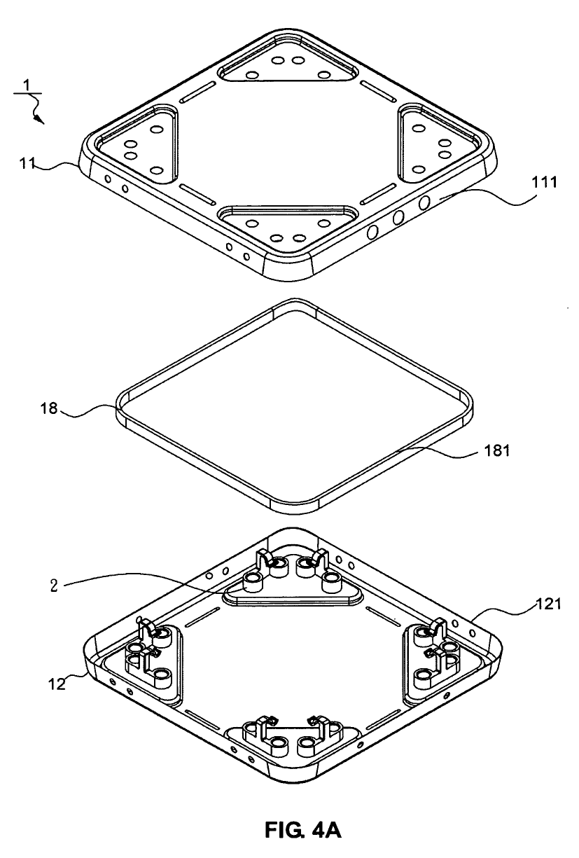

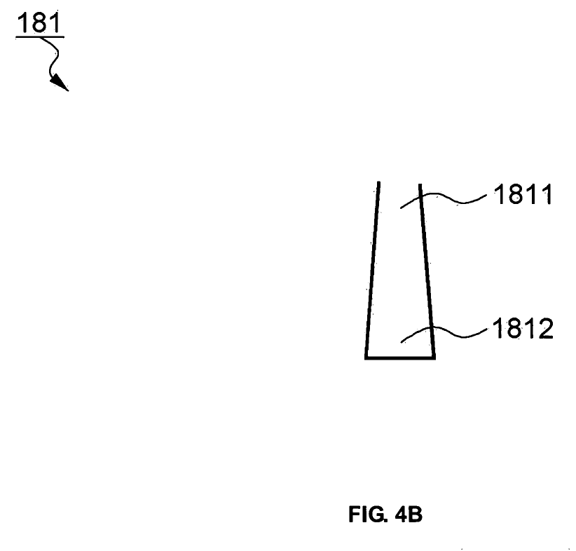

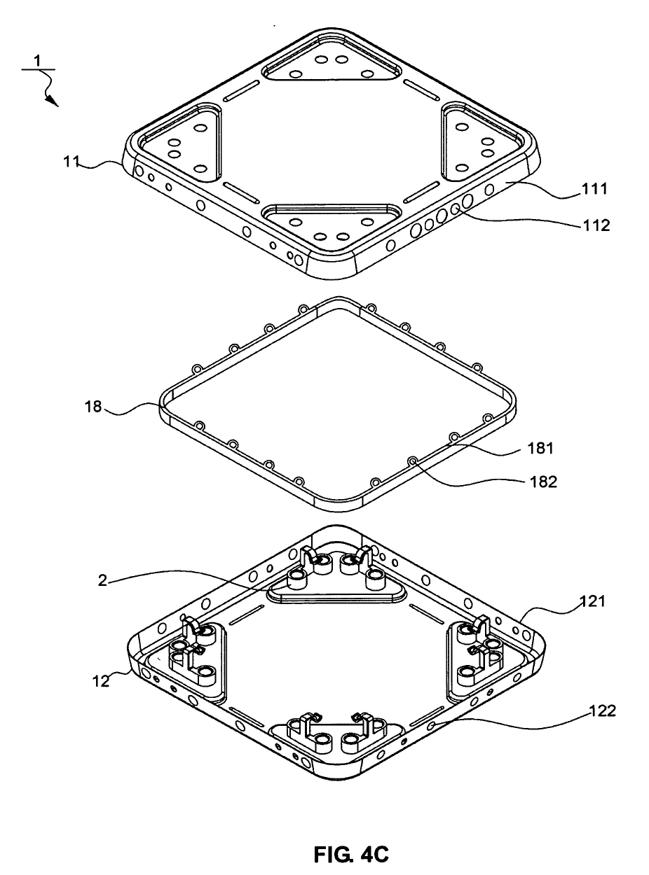

FIG. 4A illustrates another preferred embodiment of the metal photomask pod. The metal upper cover 11 of the metal photomask pod 1 includes a side portion 111 defining an opening. The metal lower cover 12 of the metal photomask pod 1 includes a side portion 121 defining an opening corresponding to the opening of the metal upper cover 11. A sealing gasket 18 is disposed on either the side portion 111 of the metal upper cover 11 or the side portion 121 of the metal lower cover 12, such that the inner space is sealed. The sealing gasket 18 is generally made of a macromolecular resin or a conductive adhesive. The sealing gasket 18 is engaged on the side portion 111 of the upper cover 11 or the side portion 121 of the lower cover 12 in a clip manner. In another preferred embodiment, the sealing gasket 18 can also be directly disposed on the side portion 111 of the upper cover 11 or the side portion 121 of the lower cover 12.

The sealing gasket 18 includes a groove 181. The sealing gasket 18 is engaged on the side portion 111 of the upper cover 11 or the side portion 121 of the lower cover 12 with the groove 181. The groove 181 has an open end 1811 and a groove bottom 1812. A width of the open end 1811 is narrower than a width of the groove bottom 1812 (seeing FIG. 4B). The sealing gasket 18 may be closely engaged with the side portions 111 or 121 directly by the above-described mechanism.

In another preferred embodiment, the present invention provides another way of engaging the sealing gasket on the side portion of the upper cover or the side portion of the lower cover. The sealing gasket 18 is engaged with the side portion 111 of the upper cover 11 or the side portion 121 of the lower cover 12 by adhesive.

The present invention provides still another preferred embodiment of engaging the sealing gasket on the side portion of the upper cover or the side portion of the lower cover. Referring to FIG. 4C, the side portion of the upper cover 11 or the lower cover 12 defines a plurality of locking holes 112 or 122. The sealing gasket 18 includes a plurality of locking ears 182 positioned corresponding to the locking holes 112 or 122. The sealing gasket 18 is engaged with the side portion 111 of the upper cover 11 or the side portion 121 of the lower cover 12 by locking members.

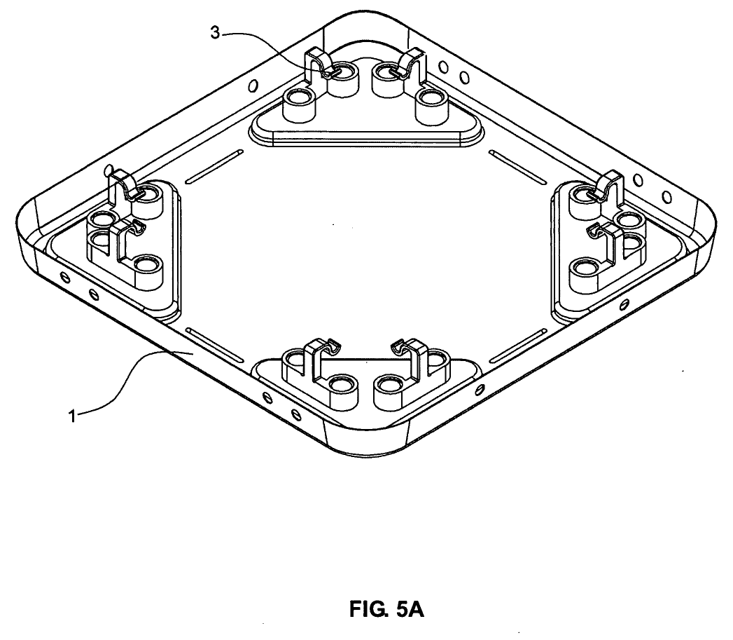

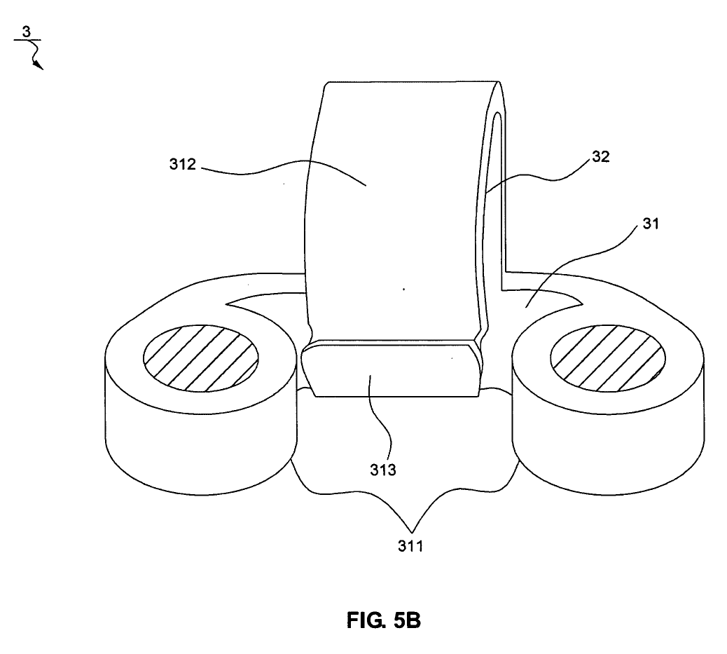

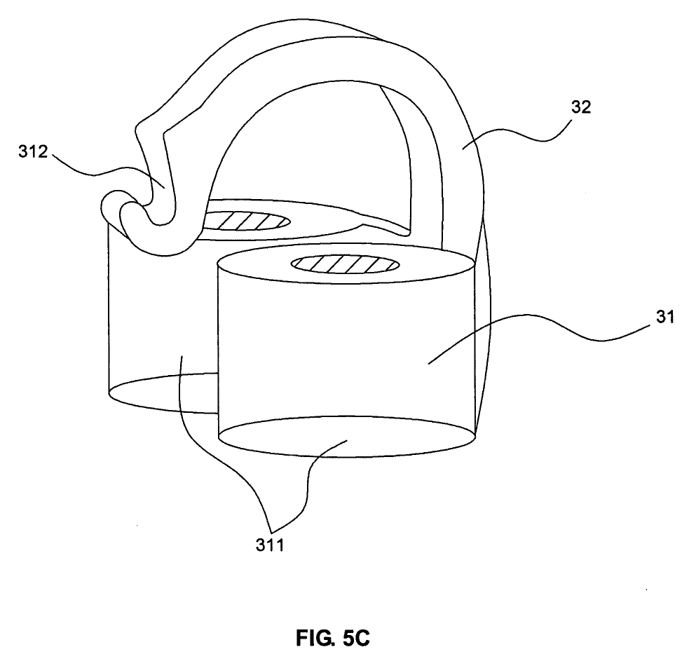

FIGS. 5A, 5B and 5C illustrate a preferred embodiment of the pressing member. The pressing member 3 includes a base 31 and at least one curved resilient member 32. The pressing member 3 is made of a high polymer material, for example. The bases 31 are mounted on corners of the upper cover 11 and the lower cover 12 of the photomask pod 1 via a plurality of support points 311. The bases 31 are arranged such that a pair of said bases 31 is disposed at each corner of the upper cover 11 and the lower cover (seeing FIG. 4A). The curved resilient member 32 includes one curved end coupled to the base 31, and another curved end disposed in a resiliently floating state between a single or a plurality of support points 311. The curved resilient member 32 further includes a support surface 312 and a pressing surface 313. As the photomask pod 1 carries a photomask and the upper cover and the lower cover are coupled together, the support surface 312 of the curved resilient member 32 can guide the photomask to a correct location. The pressing surface 313 can contact and position the photomask to prevent the photomask from being damaged that may be caused by impact during transportation of the photomask pod 1.

The present invention provides a structure that employs the sealing gasket to completely seal the upper and lower covers of the metal photomask pod, which avoids complex design while providing a satisfactory level of airtight combination. Thus, the photomask pod can not only provide the anti-ESD advantage, but also provide good airtight effect without increasing the cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A metal photomask pod, comprising:
a metal upper cover;
a metal lower cover configured to be coupled to the metal upper cover to form an inner space for receiving a photomask;
at least one through hole defined in a side portion of the metal upper cover or the metal lower cover, and configured to communicate the inner space with an outer space of the photomask pod; and
at least one filter device covering the through hole.

2. The metal photomask pod as claimed in claim 1, wherein the filter device comprises:
an elastic sleeve configured to be engaged with the through hole, and having a first opening aligned with the through hole;
a clamping member configured to be engaged in the elastic sleeve, and having at least one aperture defined at a location corresponding to the first opening; and
a filter film disposed in the clamping member where the aperture is defined.

3. The metal photomask pod as claimed in claim 2, wherein the clamping member comprises a first part and a second part coupled together.

4. The metal photomask pod as claimed in claim 3, wherein the filer film is sandwiched between the first part and the second part.

5. The metal photomask pod as claimed in claim 4, wherein at least one of the first part and the second part of the clamping member comprises a concave portion oriented toward an interior between the first part and the second part to form a space for receiving the filter film.

6. The metal photomask pod as claimed in claim 4, wherein at least one of the first part and the second part of the clamping member comprises a concave portion, while the other of the first part and the second part comprises a convex portion, in which the concave portion and the convex portion are oriented toward an interior between the first part and the second part, and the concave portion is larger than the convex portion.

7. The metal photomask pod as claimed in claim 3, wherein the first part and second part are symmetrically positioned and integrally formed elements, or separately formed elements, or two identical elements.

8. The metal photomask pod as claimed in claim 3, wherein each of the first part and the second part has the aperture.

9. The metal photomask pod as claimed in claim 2, wherein the elastic sleeve comprises a protruding portion formed around the first opening.

10. The metal photomask pod as claimed in claim 9, wherein the elastic sleeve is engaged in the through hole of the photomask pod with the protruding portion.

11. The metal photomask pod as claimed in claim 9, wherein the protruding portion of the elastic sleeve further comprises a groove portion, and the protruding portion is engaged in the through hole of the photomask pod with the groove portion.

12. The metal photomask pod as claimed in claim 2, further comprising at least one sidewall formed around the through hole, wherein the elastic sleeve is engaged with the sidewall.

13. The metal photomask pod as claimed in claim 9, further comprising at least one sidewall formed around the through hole, wherein the elastic sleeve is engaged with the sidewall with the protruding portion.

14. The metal photomask pod as claimed in claim 1, further comprising at least one sidewall formed around the through hole, wherein the sidewall is integrally formed with the upper cover or the lower cover.

15. The metal photomask pod as claimed in claim 1, further comprising at least one sidewall formed around the through hole, wherein the sidewall is attached to the upper cover or the lower cover by welding.

16. The metal photomask pod as claimed in claim 1, wherein the filter device comprises a filter sheet and a hollow frame engaged in the sidewall, such that the filter sheet is sandwiched between the hollow frame and the photomask pod.

17. The metal photomask pod as claimed in claim 1, wherein the metal photomask pod is made of stainless steel, aluminum alloy, or magnesium alloy.

18. The metal photomask pod as claimed in claim 2, wherein the elastic sleeve further comprises a second opening larger than the first opening, and a latch portion formed around the second opening to latch the clamping member.

19. The metal photomask pod as claimed in claim 2, wherein the elastic sleeve is made of a high polymer material.

20. The metal photomask pod as claimed in claim 2, wherein the clamping member is made of a metal material.

21. The metal photomask pod as claimed in claim 2, wherein the filter film is made of a synthesize fibre.

22. A filter device configured to cover a through hole of a photomask pod, wherein the through hole is configured to communicate an inner space with an outer space of the photomask pod, and the filter device comprises:
a elastic sleeve configured to be engaged in the through hole, and having a first opening aligned with the through hole;
a clamping member configured to be engaged with the elastic sleeve, and having at least one aperture defined at a location corresponding to the first opening; and
a filter film disposed in the clamping member where the aperture is defined.
